(19) United States
(12) Patent Application Publication
(10) Pub. No.: US 2011/0248763 A1
(43) Pub. Date: Oct. 13, 2011

(54) CHARGE PUMPING CIRCUIT

(75) Inventors: Chang Sun KIM, Seoul (KR); Jang Hyun Park, Seoul (KR); Seong Hoon CHOI, Seoul (KR); Young Doo SONG, Gunpo (KR); Seung Hoon SHIN, Seoul (KR); Yung Seon EO, Seongnam (KR)

(73) Assignees: IUCF-HYU (Industry-University) Cooperation Foundation Hanyang University, Seoul (KR); Electronics and Telecommunications Research Institute, Daejeon (KR)

(21) Appl. No.: 13/081,331

(22) Filed: Apr. 6, 2011

(30) Foreign Application Priority Data
Apr. 7, 2010 (KR) 10-2010-0031838

(51) Int. Cl. H03K 3/027

(52) U.S. Cl. 327/295

(57) ABSTRACT

A charge pumping circuit is provided to regulate the amount of charge to be pumped according to a driving voltage to reduce the loss of power and increase charge pumping efficiency. The charge pumping circuit includes: a driving voltage sensing unit sensing a driving voltage to generate one or more sensing signals for determining the amount of charge to be pumped; a multi-level clock generation unit generating a pair of clock signals each having an amplitude corresponding to a signal value of each of the one or more sensing signals; and a charge pumping unit charging the pair of clock signals to generate a charged voltage, adding the charged voltage to the driving voltage, and outputting the same.

### CROSS-REFERENCE TO RELATED APPLICATIONS

This application claims the priority of Korean Patent Application No. 10-2010-0031838 filed on Apr. 7, 2010, in the Korean Intellectual Property Office, the disclosure of which is incorporated herein by reference.

### BACKGROUND OF THE INVENTION

1. Field of the Invention

The present invention relates to a charge pumping circuit and, more particularly, to a charge pumping circuit for providing various charge pumping rates to improve power efficiency of a mobile device.

2. Description of the Related Art

Mobile devices, using a battery, require a charge pumping circuit for increasing voltage to be maintained at a certain level or higher when a voltage drop occurs.

Mobile devices are battery-based systems which receive input power ranging from 2.8V to 4.2V, and, in order to drive mobile devices such as an LED backlight or a touch panel, approximately 4V must be provided.

A charge pumping circuit provided to mobile devices is designed to have a voltage pumping rate of an integer multiple.

However, when the charge pumping circuit has a voltage pumping rate of an integer multiple, there may be a big difference between the voltage charge-pumped by the charge pumping circuit and the voltage actually required by a mobile device.

Namely, the related art charge pumping circuit cannot provide various voltage pumping rates, so the power efficiency of the mobile device using the charge pumping circuit is degraded.

### SUMMARY OF THE INVENTION

An aspect of the present invention provides a charge pumping circuit for variably regulating (or adjusting) a voltage pumping rate by sensing a voltage value of a driving voltage.

According to an aspect of the present invention, there is provided a charge pumping circuit including: a driving voltage sensing unit sensing a driving voltage to generate one or more sensing signals for determining the amount of charge to be pumped; a multi-level clock generation unit generating a pair of clock signals each having an amplitude corresponding to a signal value of each of the one or more sensing signals; and a charge pumping unit charging the pair of clock signals to generate a charged voltage, adding the charged voltage to the driving voltage, and outputting the same.

The driving voltage sensing unit may include one or more voltage distributors for distributing the driving voltage at different voltage distribution ratios to generate the one or more sensing signals.

Each of the one or more voltage distributors may include: a resistor and a transistor connected in series between a node to which the driving voltage is applied and a ground; and an inverter connected to a contact point of (or between) the resistor and the transistor.

Each of the one or more voltage distributors may further include: a switch connected between the node to which the driving voltage is applied and the resistor to periodically supply the driving voltage.

The multi-level clock generation unit may include: one or more reference voltage generation circuits generating one or more reference voltages each having a different voltage value; one or more switches determining whether or not the one or more reference voltages have been delivered according to the signal values of the one or more sensing signals; a ring oscillator generating a pulse signal upon receiving a voltage delivered through the one or more switches; and a nonoverlapping clock generator converting the pulse signal into a pair of clock signals and outputting the same.

The charge pumping unit may include: a pair of capacitors charging the pair of clock signals and alternately applying a charged voltage to first and second nodes; a pair of first transistors alternately applying a driving voltage to the first and second nodes; a pair of second transistors alternately delivering the voltage, which has been applied to the first and second nodes, to a third node; and an output capacitor charging the voltage applied to the third node and outputting the same to an output terminal of the charge pumping circuit.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic block diagram of a charge pumping circuit according to an exemplary embodiment of the present invention;

FIG. 2 is a circuit diagram showing a detailed configuration of a driving voltage sensing unit according to an exemplary embodiment of the present invention;

FIG. 3 is a circuit diagram showing a detailed configuration of a multi-level clock generation unit according to an exemplary embodiment of the present invention; and

FIG. 4 is a detailed block diagram of a charge pumping unit according to an exemplary embodiment of the present invention.

### DETAILED DESCRIPTION OF THE PREFERRED EMBODIMENT

The present invention may be modified variably and may have various embodiments, particular examples of which will be illustrated in drawings and described in detail.

However, it should be understood that the following exemplifying description of the invention is not intended to restrict the invention to specific forms of the present invention but rather the present invention is meant to cover all modifications, similarities and alternatives which are included in the spirit and scope of the present invention.

While terms such as “first” and “second,” etc., may be used to describe various components, such components must not be understood as being limited to the above terms. The above terms are used only to distinguish one component from another. For example, a first component may be referred to as a second component without departing from the scope of rights of the present invention, and likewise a second component may be referred to as a first component. The term “and/or” encompasses both combinations of the plurality of related items disclosed and any item from among the plurality of related items disclosed.

When a component is mentioned as being “connected” to or “accessing” another component, this may mean that it is directly connected to or accessing the other component, but it is to be understood that another component may exist therebetween. On the other hand, when a component is mentioned as being “directly connected” to or “directly accessing” another component, it is to be understood that there are no other components in-between.

The terms used in the present application are merely used to describe particular embodiments, and are not intended to limit the present invention. An expression used in the singular encompasses the expression of the plural, unless it has a clearly different meaning in the context in which it is used. In the present application, it is to be understood that the terms such as “including” or “having,” etc., are intended to indicate the existence of the features, numbers, operations, actions, components, parts, or combinations thereof disclosed in the specification, and are not intended to preclude the possibility that one or more other features, numbers, operations, actions, components, parts, or combinations thereof may exist or may be added.

Unless otherwise defined, all terms used herein, including technical or scientific terms, have the same meanings as those generally understood by those with ordinary knowledge in the field of art to which the present invention belongs. Such terms as those defined in a generally used dictionary are to be interpreted as having meanings equal to the contextual meanings in the relevant field of art, and are not to be interpreted as having ideal or excessively formal meanings unless clearly defined as having such in the present application.

Embodiments of the present invention will be described below in detail with reference to the accompanying drawings, where those components are rendered using the same reference number that are the same or are in correspondence, regardless of the figure number, and redundant explanations are omitted.

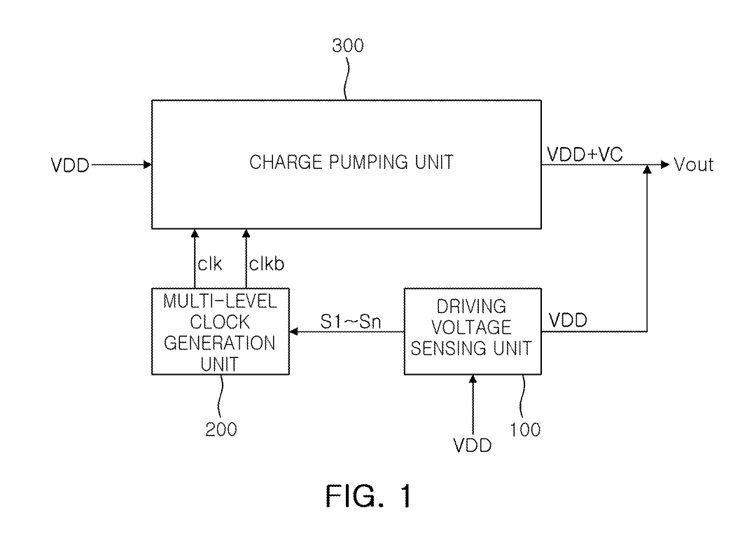

FIG. 1 is a schematic block diagram of a charge pumping circuit according to an exemplary embodiment of the present invention.

With reference to FIG. 1, a charge pumping circuit according to an exemplary embodiment of the present invention includes a driving voltage sensing unit 100, a multi-level clock generation unit 200, and a charge pumping unit 300.

The driving voltage sensing unit 100 senses a voltage value of the voltage VDD input to the charge pumping circuit and generates one or more sensing signals S1 to Sn for determining the amount of charge to be pumped.

The multi-level clock generation unit 200 generates a pair of clock signals clk and clkb having an amplitude (or a voltage level) corresponding to the signal values of the sensing signal S1 to Sn and delivers the generated pair of clock signals clk and clkb to the charge pumping unit 300.

The charge pumping unit 300 charges the pair of clock signals clk and clkb to alternately generate a charged voltage VC, and adds the charged voltage VC to a driving voltage VDD to generate an output voltage Vout. Namely, the charge pumping unit 300 charge-pumps the driving voltage VDD by using the charged voltage VC which has been generated by charging the pair of clock signals clk and clkb.

In the charge pumping circuit configured as shown in FIG. 1, when the driving voltage VDD input to the charge pumping circuit is higher than a voltage required by its output terminal, the charge pumping circuit outputs the driving voltage VDD as it is to the output terminal, while when the driving voltage VDD is lower than the voltage required by the output terminal, the charge pumping circuit generates one or more sensing signals S1 to Sn for determining the amount of charge to be pumped of the driving voltage VDD through the driving voltage sensing unit 100.

Then, the multi-level clock generation unit 200 regulates the amplitude of each of the pair of clock signals clk and clkb according to the signal values of the one or more sensing signals S1 to Sn, and the charge pumping unit 300 performs a charging operation by using the pair of clock signals clk and clkb to generate a first or second voltage VC, and adds the first or second charge voltage VC to the driving voltage VDD to generate the output voltage VOUT.

A charge pumping rate (M) of the charge pumping circuit can be represented by Equation 1 shown below:

$$M = \frac{VOUT}{V D D} = \frac{V D D + V C}{V D D} = 1 + \frac{V C}{V D D} \qquad [ Equation 1 ]$$

As shown in Equation 1, it is noted that the charge pumping rate (M) is determined according to the charged voltage VC generated by the pair clock signals clk and clkb. The amplitude of each of the pair of clock signals clk and clkb can be variably adjusted (or regulated) according to the results obtained by sensing the driving voltage VDD.

Namely, the charge pumping circuit variably adjusts the voltage value of the charged voltage VC according to the voltage value of a currently input driving voltage and variably adjusts the charge pumping rate (M) accordingly.

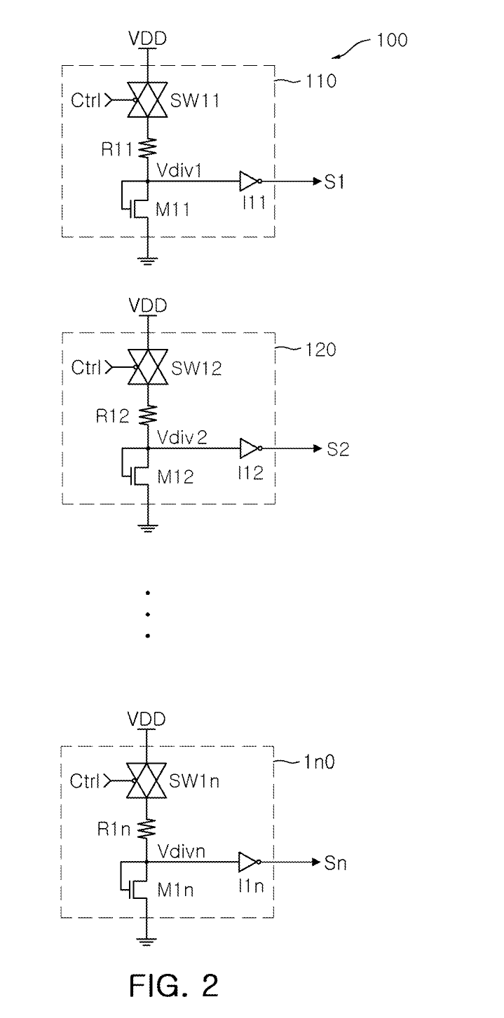

FIG. 2 is a circuit diagram showing a detailed configuration of a driving voltage sensing unit according to an exemplary embodiment of the present invention.

With reference to FIG. 2, the driving voltage sensing unit 100 includes one or more voltage distributors 110 to 1n0 for distributing the driving voltage VDD to generate the one or more sensing signals S1 to Sn.

In this case, the driving voltage sensing unit 100 may include one voltage distributor or a plurality of voltage distributors. When the driving voltage sensing unit 100 includes a plurality of voltage distributors, preferably, the plurality of voltage distributors have different voltage distribution rates to have different sensing sections, respectively.

In FIG. 2, the case in which the driving voltage sensing unit 100 includes the plurality of voltage distributors 110 to 1n0 will be taken as an example, for the sake of brevity.

With reference to FIG. 2, the voltage distributors 110 to 1n0 include resistors R11 to R1n and transistors M11 to M1n connected in series between a node to which the driving voltage VDD is applied and a ground, and inverters I11 to I1n connected to a contact point of the resistors R11 to R1n and the transistors M11 to M1n, respectively. In this case, a drain and a gate of each of the transistors M11 to M1n are commonly connected to one end of each of the resistors R11 to R1n.

Also, the respective voltage distributors 110 to 1n0 may further include switches SW11 to SW1N positioned between a node to which the driving voltage VDD is applied and the resistors R11 to R1n to determine whether to supply the driving voltage VDD according to a sensing operation control signal ctrl1. This is because, when the driving voltage VDD is supplied by a battery of a mobile device, the voltage of the driving voltage VDD is slowly dropped, rather than being rapidly dropped at once, so the driving voltage sensing unit 100 may be periodically activated through the switches SW11 to SW1n to improve power efficiency of the charge pumping circuit.

On the assumption that the current flowing across the resistors R11 to R1n and the current flowing across the transistors M11 to M1n are equal, the voltage distributors 110 to 1n0 distribute the driving voltage VDD according to Equation 2 shown below:

$$V D D {-}_{R} Vdlv = {{{β}_{N}}_{2} ( \begin{matrix}Vdlv & Vth\end{matrix} )}^{2} \\ Vdlv = Vth + \sqrt{\frac{2 \cdot \frac{V D D - Vdlv}{R}}{{β}_{N}}} \qquad [ Equation 2 ]$$

Here, VDD is a driving voltage, Vdiv is a driving voltage distributed by the voltage distributor, R is a resistance, β_{N} is a transistor voltage gain, and Vth is a threshold voltage of a transistor.

With reference to Equation 2, it is noted that a voltage distribution rate of each of the voltage distributors 110 to 1n0 is determined according to a resistance value of each of the resistors R11 to R1n and the transistor voltage gain β_{N}, and the transistor voltage gain β_{N} is determined according to a gate width (W) and a gate length (L) of each of the transistors M11 to M1n.

Thus, in the present exemplary embodiment, the resistance value of each of the resistors R11 to R1n and the gate width (W) and the gate length (L) of each of the transistors M11 to M1n are adjusted to allow the plurality of voltage distributors 110 to 1n0 to have a different voltage distribution rate.

For example, the voltage distribution rates of the respective voltage distributors 110 to 1n0 may be set such that the voltage distributor 110 positioned at a first stage generates a distributed voltage Vdiv1 has the highest voltage value, and the distributed voltages Vdiv2 to Vdivn are generated to have voltage values which are diminished toward the rear stage.

When the voltage distribution rates of the respective voltage distributors 110 to 1n0 are set to be different, the driving voltage sensing unit 100 has sensing sections proportionate to the number of the voltage distributors 110 to 1n0. Namely, the driving voltage VDD may be sensed with the sections of “the number of voltage distributors 110 to 1n0 +1”.

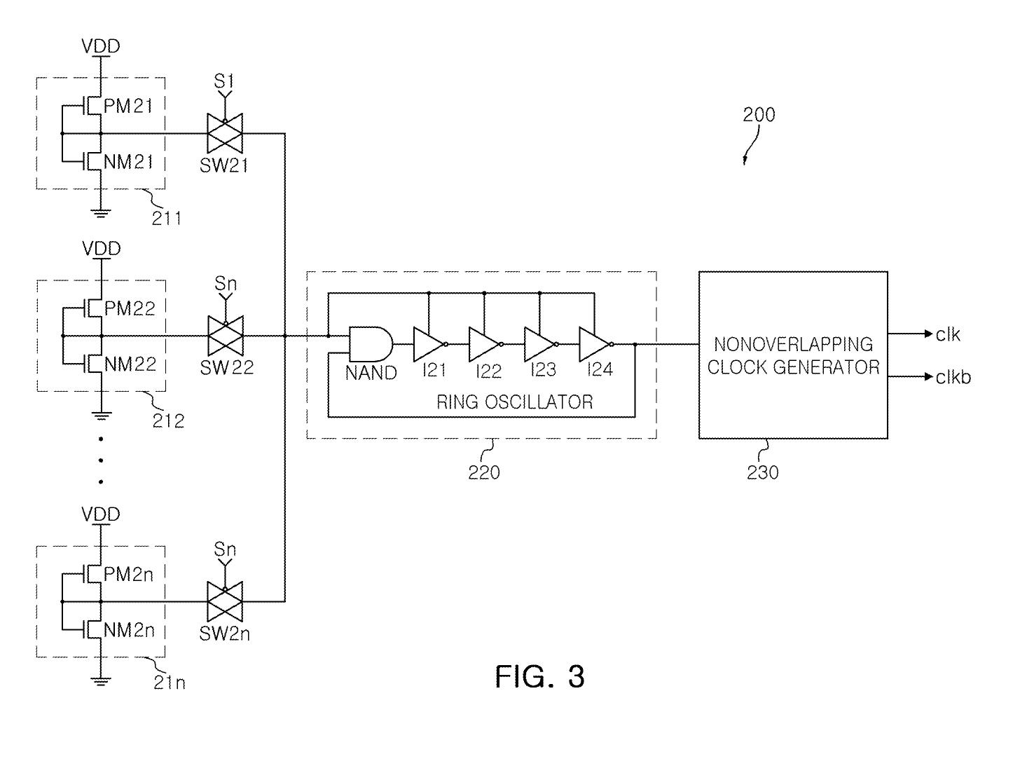

FIG. 3 is a circuit diagram showing a detailed configuration of a multi-level clock generation unit according to an exemplary embodiment of the present invention.

With reference to FIG. 3, the multi-level clock generation unit 200 includes one or more reference voltage generation circuits 211 to 21n generating one or more reference voltages Vref1 to Vrefn, one or more switches SW21 to SW2n for determining whether to deliver the respective reference voltages Vref1 to Vrefn according to signal values of one or more sensing signals S1 to Sn provided from the driving voltage sensing unit 100, a ring oscillator 220 generating pulse signals upon receiving voltages delivered through the one or more switches SW21 to SW2n, and a nonoverlapping clock generator 230 converting the pulse signals into a pair of clock signals clk and clkb and outputting the same.

The multi-level clock generation unit 200 may include one reference voltage generation circuit and one switch or a plurality of reference voltage generation circuits and a plurality of switches. When the multi-level clock generation unit 200 includes a plurality of reference voltage generation circuits, preferably, the plurality of reference voltage generation circuits generate reference voltages having different voltage values.

In FIG. 3, a case in which the multi-level clock generation unit 200 includes a plurality of reference voltage generation circuits 211 to 212n and switches SW21 to SW2n will be taken as an example, for the sake of brevity.

With reference to FIG. 3, the respective reference voltage generation circuits 211 to 21n include pairs of first transistors NM21 and PM21 to NM2n and PM2n connected in series between a node to which the driving voltage VDD is applied and a ground. The ring oscillator 220 includes a NAND gate for NANDing voltages delivered from the plurality of switches SW21 to SW2n and an output from the ring oscillator 220, and an even number of inverters I21 to I24 connected in series to an output terminal of the NAND gate NAND.

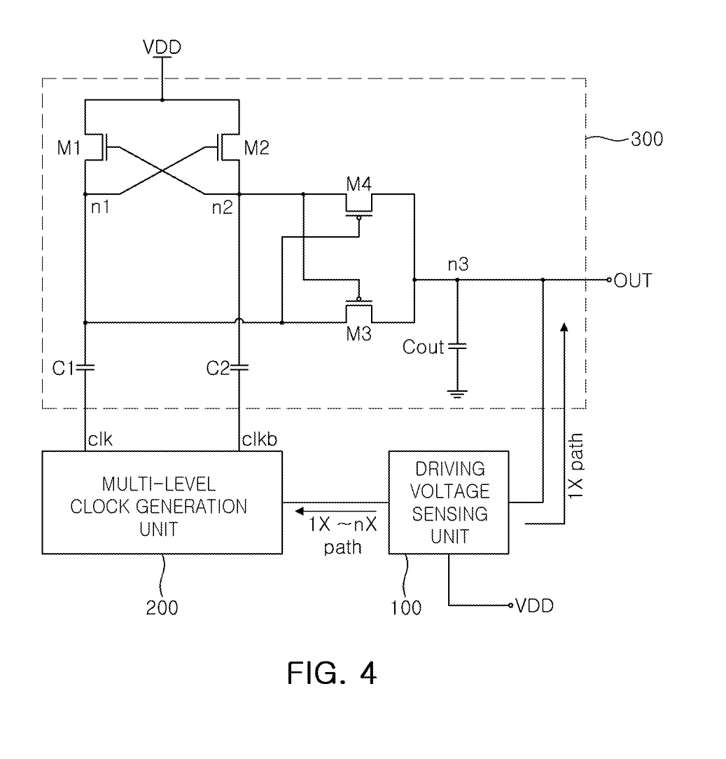

When the plurality of sensing signals S1 to Sn are provided from the driving voltage sensing unit 100, the multi-level clock generation units 200 in FIG. 4 variably adjusts the voltage applied to an input terminal of the ring oscillator in response thereto.

When a plurality of sensing signals S1 to Sn indicating that a driving voltage VDD having a voltage value higher than that of a required voltage has been input are provided from the driving voltage sensing unit 100 (e.g., when a plurality of sensing signals S1 to Sn having signal values (0, 0, . . . , 0) are provided), the switches SW21 to SW2n are all turned off to interrupt a voltage supply to the ring oscillator 220. Then, the ring oscillator 220 and the nonoverlapping clock generator 230 are deactivated to stop generating the pair of clock signals clk and clkb, and the charge pumping unit 300 delivers the driving voltage VDD as it is to the output terminal without performing a charge pumping operation using the pair of clock signals clk and clkb.

Namely, when the driving voltage VDD having a voltage value higher than that of a required voltage is input from the driving sensing unit 100, a charge pumping operation is not required, so the multi-level clock generation unit 200 stops generating the pair of clock signals clk and clkb so that the driving voltage VDD can be delivered to the output terminal as it is.

Meanwhile, when a plurality of sensing signals S1 to Sn indicating that a driving voltage VDD having a voltage value lower than that of a required voltage has been input and indicating an amount of charge required to be pumped are provided from the driving voltage sensing unit 100 (e.g., when a plurality of sensing signals S1 to Sn having signal values (1, 0, . . . , 0) are provided), a corresponding switch (e.g., SW21) is turned on to provide a corresponding reference voltage to the ring oscillator 220. Then, the ring oscillator 220 generates a pulse signal having the reference voltage applied to its input terminal as a high level and a ground as a low level, and the nonoverlapping clock generator 230 converts the pulse signal into a pair of clock signals clk and clkb and outputs the same to the charge pumping unit 300.

Then, the charge pumping unit 300 generates a charged voltage by using the pair of clock signals clk and clkb, adds them to the driving voltage VDD, and outputs the same. Namely, the charge pumping unit 300 charge-pumps the driving voltage VDD by using the pair of clock signals clkb and clkb and outputs the same to eth output terminal.

In this manner, the multi-level clock generation unit 200 variably adjusts the amplitudes of the pair of clock signals provided to the charge pumping unit 300 according to the signal values of the plurality of sensing signals S1 to Sn provided from the driving voltage sensing unit 100.

FIG. 4 is a detailed block diagram of a charge pumping unit according to an exemplary embodiment of the present invention.

With reference to FIG. 4, the charge pumping unit includes a pair of first transistors M1 and M2 whose drains, gates, and sources, to which the driving voltage VDD is applied, are cross-linked, a pair of capacitors C1 and C2 charging the pair of clock signals clk and clkb provided from the multi-level clock generation unit 200 and applying the charged voltage VC to the sources of the pair of first transistors M1 and M2, a pair of second transistors M3 and M4 whose gates and sources are cross-linked to the sources of the pair of first transistors M1 and M2, and an output capacitor Cout connected between a common drain of the pair of second transistors M3 and M4 and a ground.

When the driving voltage VDD is supplied to the charge pumping unit 300, the pair of first transistors M1 and M2 alternately apply the driving voltage VDD to first and second nodes n1 and n2.

In this state, when the pair of clock signals clk and clkb are additionally supplied from the multi-level clock generation unit 200, the pair of capacitors C1 and C2 charge the pair of clock signals clk and clkb to generate the charged voltage VC and alternately apply the generated charged voltage to the first and second nodes n1 and n2.

As a result, the voltage of “VDD+VC” is alternately applied to the first and second nodes n1 and n2, and the voltage is finally output to the output terminal of the charge pumping circuit through the pair of second transistors M3 and M4.

In this manner, the charge pumping unit 300 variably regulates the charged voltage VC according to the amplitudes of the pair of clock signals clk and clkb from the multi-level clock generation unit 200, thus eventually variably adjusting even the charge pumping rate.

As set forth above, according to exemplary embodiments of the invention, the charge pumping circuit can variably adjust a pumping rate according to a voltage value of a driving voltage to thus provide an appropriate charge-pumped voltage as required by a mobile device.

Thus, because the mobile device using the charge pumping circuit can be always provided with the required voltage, it can have a high level of power efficiency.

While the present invention has been shown and described in connection with the exemplary embodiments, it will be apparent to those skilled in the art that modifications and variations can be made without departing from the spirit and scope of the invention as defined by the appended claims.

What is claimed is:

1. A charge pumping circuit comprising:
a driving voltage sensing unit sensing a driving voltage to generate one or more sensing signals for determining the amount of charge to be pumped;
a multi-level clock generation unit generating a pair of clock signals, each having an amplitude corresponding to a signal value of each of the one or more sensing signals; and
a charge pumping unit charging the pair of clock signals to generate a charged voltage, adding the charged voltage to the driving voltage, and outputting the same.

2. The circuit of claim 1, wherein the driving voltage sensing unit comprises one or more voltage distributors for distributing the driving voltage at different voltage distribution ratios to generate the one or more sensing signals.

3. The circuit of claim 1, wherein each of the one or more voltage distributors comprises:
a resistor and a transistor connected in series between a node to which the driving voltage is applied and a ground; and
an inverter connected to a contact point of the resistor and the transistor.

4. The circuit of claim 3, wherein each of the one or more voltage distributors further comprises a switch connected between the node to which the driving voltage is applied and the resistor to periodically supply the driving voltage.

5. The circuit of claim 1, wherein the multi-level clock generation unit comprises:
one or more reference voltage generation circuits generating one or more reference voltages each having a different voltage value;
one or more switches determining whether or not the one or more reference voltages have been delivered according to the signal values of the one or more sensing signals;
a ring oscillator generating a pulse signal upon receiving a voltage delivered through the one or more switches; and
a nonoverlapping clock generator converting the pulse signal into a pair of clock signals and outputting the same.

6. The circuit of claim 1, wherein the charge pumping unit comprises:
a pair of capacitors charging the pair of clock signals and alternately applying a charged voltage to first and second nodes;
a pair of first transistors alternately applying a driving voltage to the first and second nodes;
a pair of second transistors alternately delivering the voltage, which has been applied to the first and second nodes, to a third node; and
an output capacitor charging the voltage applied to the third node and outputting the same to an output terminal of the charge pumping circuit.
